(19) United States
(12) Patent Application Publication
(10) Pub. No.: US 2025/0280633 A1
(43) Pub. Date: Sep. 4, 2025

(54) DISPLAY PANEL

(71) Applicant: AUO Corporation, Hsinchu City (TW)

(72) Inventors: Chun-Wei HUANG, Hsinchu City (TW); Wei-Kai LEE, Hsinchu City (TW); Jung-Hsien HSU, Hsinchu City (TW); Tzu-Chi WANG, Hsinchu City (TW); Chung-Chih WU, Hsinchu City (TW); Yu-Hsin HUANG, Hsinchu City (TW); Kuan-Heng LIN, Hsinchu City (TW)

(21) Appl. No.: 18/932,089

(22) Filed: Oct. 30, 2024

(30) Foreign Application Priority Data
Feb. 29, 2024 (TW) 113107212

(51) Int. Cl. H01L 33/60; H01L 25/075

(52) U.S. Cl. CPC H10H 20/856; H01L 25/0753

(57) ABSTRACT

The present invention provides a display panel including: a substrate; a light emitting unit disposed on the substrate and having a top away from the substrate, a bottom opposite to the top, and a side wall connecting the top and the bottom; an angle-selective optical film disposed on the top of the light emitting unit; and a protective layer covering the light emitting unit and the angle-selective optical film. With respect to a normal line vertical to the substrate, display light emitted to the angle-selective optical film by the light emitting unit has an incident angle, and the ratio of the display light reflected by the angle-selective optical film varies at least partially based on the change of the incident angle. The bottom, the side wall, or a combination thereof has an optical structure configured to at least partially reflect the display light reflected from the angle-selective optical film.

### CROSS-REFERENCE TO RELATED APPLICATION

This application claims the priority benefit of Taiwan application serial no. 113107212 filed on Feb. 29, 2024. The entirety of the above-mentioned patent application is hereby incorporated by reference herein and made a part of this specification.

### TECHNICAL FIELD

The present invention relates to a display panel having an angle-selective optical film. Specifically, the present invention relates to a display panel having an angle-selective optical film that can change a reflectance according to an incident angle.

### BACKGROUND

As the fineness and intensity of light emitting units used in a display panel increase, the light emitting units may require more protective or positioning structures to protect and maintain the structure and arrangement of the light emitting units. However, various protective or positioning structures may reduce or hinder light emitting of the light emitting units, and may correspondingly reduce or deteriorate the light emitting efficiency and light emitting quality of the light emitting units. Therefore, it is needed to develop technologies that can reduce or avoid the reduction or deterioration of the light emitting efficiency and light emitting quality in the premise of improving or ensuring the protection or positioning of the light emitting units.

### SUMMARY

### Technological Means for Solving Problems

In order to solve above problems, the present invention provides a display panel, which includes: a substrate; a light emitting unit disposed on the substrate and having a top facing away from the substrate, a bottom opposite to the top, and a side wall connecting the top and the bottom; an angle-selective optical film disposed on the top of the light emitting unit; and a protective layer covering the light emitting unit and the angle-selective optical film. With respect to a normal line vertical to the substrate, display light emitted to the angle-selective optical film by the light emitting unit has an incident angle, and the ratio of the display light reflected by the angle-selective optical film varies at least partially based on the change of the incident angle. The bottom, the side wall, or a combination thereof has an optical structure configured to at least partially reflect the display light reflected from the angle-selective optical film.

### Benefits in Comparison with Prior Art

According to the display panel provided by each embodiment of the present invention, the light emitting efficiency of the display light emitted by the light emitting unit can be further improved in the premise of ensuring or improving the positioning or protection of the light emitting unit.

### BRIEF DESCRIPTION OF THE DRAWINGS

FIG. 1 is a schematic three-dimensional view of a display panel having at least one light emitting unit according to an embodiment of the present invention.

FIG. 2 is a schematic sectional view of a part of a display panel taken along a section line X-X′ of FIG. 1 according to an embodiment of the present invention.

FIG. 3 is a schematic sectional view of a specific structure of a light emitting unit according to another embodiment of the present invention.

FIG. 4 is a schematic sectional view of a specific structure of a light emitting unit according to yet another embodiment of the present invention.

FIG. 5A to FIG. 5H are sequential schematic diagrams showing the preparation of a light emitting unit of a display panel according to an embodiment of the present invention.

FIG. 6 is a test result view of reflectance and transmittance of an angle-selective optical film corresponding to different incident angles according to each embodiment of the present invention.

FIG. 7 is a test result view of radiant intensity of light emitting of a display panel according to each embodiment of the present invention.

FIG. 8 is a test result view of light emitting efficiency improvement factor of a display panel according to each embodiment of the present invention.

FIG. 9 is a schematic view of a configuration architecture of a light emitting unit of a display panel according to yet another embodiment of the present invention.

### DETAILED DESCRIPTION

Various embodiments are described below, and those skilled in the art can easily understand the spirit and principles of the present invention with reference to the description and the accompanying drawings. However, while some specific embodiments are specified here, they are illustrative only and are not considered to be restrictive or exhaustive in any aspects. Therefore, for those skilled in the art, various changes and modifications to the present invention should be obvious and easily achievable without departing from the spirit and principles of the present invention.

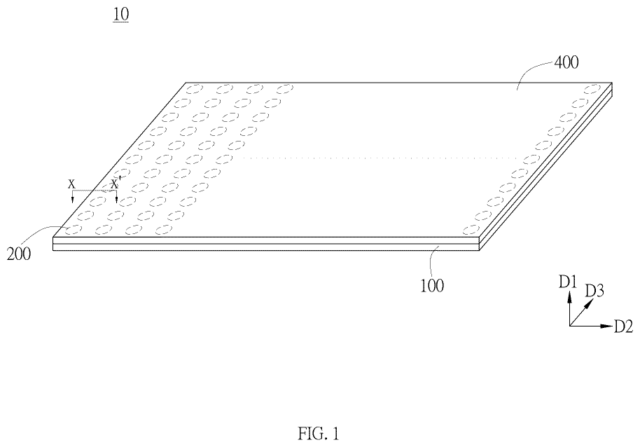

With reference to FIG. 1, an embodiment of the present invention provides a display panel 10, which may sequentially stack in a vertical first direction D1 to include a substrate 100, at least one light emitting unit 200 disposed on the substrate 100, and a protective layer 400 covering the at least one light emitting unit 200 to protect and/or position the at least one light emitting unit 200. The at least one light emitting unit 200 are arranged in a second direction D2 and a third direction D3 that are vertical to the first direction D1. For example, according to some embodiments, the display panel 10 may be a micro LED display panel (i.e., a uLED display panel), and includes a plurality of micro LEDs (i.e., uLEDs) that may respectively emit light independently as the light emitting units 200. As described above, in order to protect and/or position the micro LEDs, the protective layer 400 made of an optical adhesive (OC) may be arranged on the plurality of micro LEDs to ensure that the micro LEDs are not directly exposed to cause damage or shift. However, the above is only illustrative, and the type of the light emitting units 200, the type or material of the protective layer 400, or the like according to other embodiments of the present invention may be not limited to these. For example, the light emitting units 200 may alternatively be mini LEDs. As described above, the description of the details of variations in these different aspects might be omitted here.

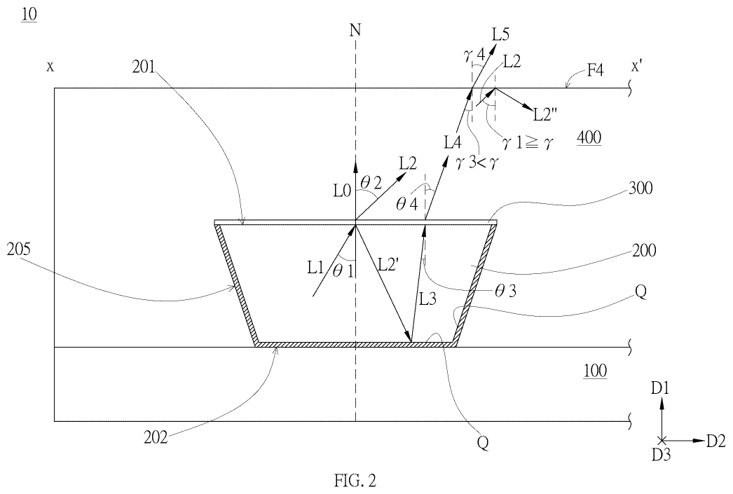

Then, with further reference to FIG. 2 that is an enlarged sectional view taken along a section line X-X′ of FIG. 1, the light emitting unit 200 may have a top 201 facing away from the substrate 100 in the first direction D1, a bottom 202 opposite to the top 201 in the first direction D1, and a side wall 205 connecting the top 201 and the bottom 202. The display panel 10 according to this embodiment may further include an angle-selective optical film 300 disposed on the light emitting top 201 of the light emitting unit 200. For example, as shown in FIG. 2, the angle-selective optical film 300 may at least partially or mostly cover the top 201 of the light emitting unit 200 and is disposed between the light emitting unit 200 and the protective layer 400. Based on this structure, the protective layer 400 may correspondingly cover the light emitting unit 200 and the angle-selective optical film 300, and at least part of display light emitted by the light emitting unit 200 is emitted to the protective layer 400 only after passing through the angle-selective optical film 300. For example, except openings formed at positions such as necessary component clamping positions or wire connecting positions, the protective layer 400 may correspondingly completely cover the light emitting unit 200 and the angle-selective optical film 300, so that most of the display light emitted by the light emitting unit 200 is emitted to the protective layer 400 only after passing through the angle-selective optical film 300.

As described above, according to each embodiment of the present invention, the angle-selective optical film 300 may be a film layer having different reflectance and transmittance for light with different incident angles. For example, according to some embodiments, the angle-selective optical film 300 may be a film layer formed by sequentially stacking different material layers, and each material layer may have a respective adjusted thickness such that the angle-selective optical film 300 may have different transmittance and reflectance relative to the light incident at different incident angles. That is, in this aspect, each material layer having different refractive indexes of the angle-selective optical film 300 may have a different and respective adjusted thickness such that a screening property can be relatively generated for the light incident according to different incident angles when passing through each material layer. As described above, the angle and optical effects of such light will be described below based on single-direction section taken as an example. However, those skilled in the art should understand that sections in other directions may or may not have the same or similar optical properties, which will not be listed here.

As described above, with reference to FIG. 2, according to an embodiment of the present invention, the section taken along the section line of X-X′ is parallel to a normal line N that is vertical to the substrate 100 in the first direction D1, and display light L1 emitted by the light emitting unit 200 to the angle-selective optical film 300 may have an incident angle θ1. The ratio of the display light L1 reflected from the angle-selective optical film 300 and/or the ratio of the display light L1 transmitted through the angle-selective optical film 300 may at least partially vary based on the change of the incident angle θ1. As described above, according to this embodiment, the angle-selective optical film 300 may be set to have high reflectance for a range of a larger incident angle θ1 and have low reflectance for a range of a smaller incident angle θ1, or the angle-selective optical film 300 may be set to have low transmittance for a range of a larger incident angle θ1 and have high transmittance for a range of a smaller incident angle θ1. For example, according to some embodiments, it may be set as that when the incident angle θ1 is greater than a preset angle, the reflectance of the angle-selective optical film 300 reflecting the display light L1 is greater than the transmittance of the angle-selective optical film 300 transmitting the display light L1. Alternatively, according to some other embodiments, it may be set as that the variation rate of the reflectance of the angle-selective optical film 300 reflecting the display light L1 when the incident angle θ1 is greater than the preset angle is greater than the variation rate of the reflectance of the angle-selective optical film 300 reflecting the display light L1 when the incident angle θ1 is smaller than the preset angle.

As described above, according to some embodiments, by disposing the angle-selective optical film 300 between the light emitting unit 200 and the protective layer 400, the incident angle θ1 corresponding to an original specific transmittance and/or specific reflectance at the interface between the light emitting unit 200 and the protective layer 400 can be changed. For example, the interface between the light emitting unit 200 and the protective layer 400 may originally exhibit a reflectance of 25% approximately at an incident angle θ1 of around 30°. After the angle-selective optical film 300 is further disposed, an incident angle θ1 of around 20° corresponding to the reflectance of 25% can be adjusted. Therefore, the range of the incident angle θ1 may be selected, and the ratio of the light in the range of the specific incident angle θ1 to be emitted to the protective layer 400 through the angle-selective optical film 300 is increased or reduced. Therefore, according to each embodiment of the present invention, through the adjustment of the angle-selective optical film 300, the change of the transmittance and/or reflectance based on the relative incident angle θ1 may enable the light even with the same wavelength or in the same wavelength range have different transmittance and/or reflectance when the incident angle θ1 varies.

As described above, with reference to FIG. 2, when the display light L1 is emitted to the angle-selective optical film 300 at the incident angle θ1, a part of the display light L1 may be transmitted through the angle-selective optical film 300 at the incident angle θ1 to form display light L2 emitted to the protective layer 400 at an emergent angle θ2, and a part of the display light L1 may be reflected by the angle-selective optical film 300 to form display light L2′ emitted back to the light emitting unit 200. The ratio of the display light L2 to the display light L2′ varies based on the change of the incident angle θ1 according to the design of the angle-selective optical film 300.

Continuing to reference FIG. 2, according to this embodiment, the bottom 202, the side wall 205, or a combination thereof of the light emitting unit 200 may further have an optical structure Q configured to at least partially reflect the display light L2′ reflected from the angle-selective optical film 300. Specifically, according to this embodiment, the optical structure Q may be provided to at least partially retrieve and reflect the light emitted from the light emitting unit 200 and not directly emitted to the angle-selective optical film 300, or the display light L2′ that is not transmitted through the angle-selective optical film 300 and is reflected back. As described above, the display light L2′ may be reflected by the optical structure Q to form display light L3 that is re-emitted to the angle-selective optical film 300. At least part of the display light L3 may be re-emitted to the angle-selective optical film 300 at an incident angle θ3 different from the original incident angle θ1, and therefore transmitted through the angle-selective optical film 300 to form display light L4 that is emitted into the protective layer 400 at an emergent angle θ4. Therefore, according to this embodiment, the light emitted from the light emitting unit 200 to the protective layer 400 may be increased within the range of at least part of a specific incident angle and decreased within the range of at least part of a specific incident angle according to selective transmission and/or reflection at different incident angles θ1 by the angle-selective optical film 300 and the optical structure Q that may reflect and retrieve the light. In addition, it is possible to further enable the light emission within the range of the specific incident angle θ1, whose the light emergent ratio has been decreased, to be altered in another incident angle and thereby enable the light to be emitted within the range of the expected incident angle θ3. Therefore, the emergent angle or pattern of the entire display light may correspondingly vary. Further, it is possible to correspondingly reduce or avoid the emission of at least part of the display light that is originally emitted to the protective layer 400 but is difficult to be further emitted to the outside (such as air), and to additionally change such display light to now be capable of emitting through the protective layer 400 and further to the outside.

Specifically, according to this embodiment, when the emergent angle is too large, at least part of the display light emitted from the light emitting unit 200 to the protective layer 400 may be reflected on an interface F4 between the protective layer 400 and the outside. For example, according to some embodiments, the display light L2 and the display light L4 emitted from the light emitting unit 200 to the protective layer 400 are compared relatively, the former may have a larger emergent angle θ2, and the latter may have a smaller emergent angle θ4. As described above, the display light of the light emitting unit 200 may have a critical angle of total reflection γ at the interface F4 between the protective layer 400 (such as optical adhesive, refractive index=1.5) and the outside of the protective layer 400 (such as air, refractive index=1). Corresponding to the emergent angle θ2, the display light L2 may have a large incident angle γ1 when being emitted to the interface F4, and the incident angle γ1 may be greater than or equal to the critical angle of total reflection γ. Therefore, the display light L2 is totally reflected at the interface F4 to form display light L2″ that is reflected and cannot be emitted to the outside. In contrast, corresponding to the emergent angle θ4, the display light L4 may have a small incident angle γ3 when being emitted to the interface F4, and the incident angle γ3 may be smaller than the critical angle of total reflection γ, so that the display light L4 is more easily emitted from the protective layer 400 to form the display light L5 which is emitted to the outside of the protective layer 400 at an emergent angle γ4. For example, the emergent angle θ4 of the display light L4 transmitted to the protective layer 400 through the angle-selective optical film 300 is smaller than the critical angle of total reflection γ, and the display light L4 travels approximately straight within the protective layer 400 so that the emergent angle θ4 is equal to the incident angle γ3. As described above, the emergent angle θ4 of the display light L4 which is incident to the angle-selective optical film 300 at an incident angle θ3 smaller than a preset angle and correspondingly passes through the angle-selective optical film 300 may be smaller than the critical angle of total reflection γ, so that the actual proportion of the display light L4 emitted to the protective layer 400 to the outside may be further improved.

As described above, based on the arrangement of the angle-selective optical film 300, the display light L2 emitted at the emergent angle θ2 formed by the transmission of display light L1 may be at least partially reduced or greatly avoided; and the display light L2′ reflected by the display light L1 may be correspondingly retrieved, and the display light L4 emitted at the emergent angle θ4 is correspondingly formed. As described above, the display light L2 emitted to the protective layer 400 is relatively difficult to be emitted to the outside of the protective layer 400, and the display light L4 emitted to the protective layer 400 is relatively easy to be emitted to the outside of the protective layer 400, so the overall actual light emitting amount of the light emitted from the light emitting unit 200 of the display panel 10 to the outside can be substantially increased according to this embodiment, and the problem of light being lost or trapped due to emission into the protective layer 400 but being unable to emit to the outside is reduced or avoided. Therefore, based on this embodiment, the light emitting amount and the light emitting efficiency of the display panel 10 can be improved.

According to some embodiments, the above preset angle may be, for example, any angle between 15° and 45°, or any angle between 18° and 40°, or any angle between 20° and 35°, or any angle between 20° and 30°, or any angle between 20° and 24°. As described above, the preset angle may be adjusted according to the incident angle of the light which is expected to be easily emitted to the protective layer 400 but cannot be emitted to the outside and is lost or trapped.

Specifically, according to some embodiments, under the condition that the angle-selective optical film 300 is not arranged, and when the incident angle is within a first angle range with the minimum angle, most of display light may be emitted to the protective layer 400 from the light emitting unit 200 and further emitted to the outside of the protective layer 400 to display light; when the incident angle is within a second angle range with the angle relatively greater than that of the first angle range, most of the display light may be emitted to the protective layer 400 from the light emitting unit 200 but is difficult to be further emitted to the outside of the protective layer 400; and when the incident angle is within a third angle range with the angle relatively greater than that of the second angle range, the display light is possibly difficult to be emitted to the protective layer 400 from the light emitting unit 200. As described above, the display light within the second angle range is relatively difficult to be emitted to the outside to display, such that display light which is easily lost or trapped in the protective layer 400 is easily formed. Therefore, according to this embodiment, by arranging the angle-selective optical film 300, the display light within the second angle range is reduced or avoided being emitted to the protective layer 400, and the display light, which is originally possibly lost or trapped in the second angle range, can be reduced or avoided. In addition, the display light within the second angle range may be further changed to be emitted at the incident angle within the first angle range, thereby increasing the light emitting amount and the light emitting efficiency of the display light actually emitted to the outside.

According to some embodiments, the first angle range may be, for example, 0° to 20°, the second angle range may be, for example, 20° to 40°, and the third angle range may be, for example, 40° to 90°. As described above, according to this embodiment, based on the adjustment to the reflectance and refractive index under the preset angle, the display light is reduced or avoided from being incident to the top 201 of the light emitting unit 200 within the second angle range and emitted, and the display light may be incident to the top 201 of the light emitting unit 200 within the first angle range and emitted, thus correspondingly reducing or avoiding light loss or trapping, and increasing or improving the light emitting amount and the light emitting efficiency of the display light actually emitted to the outside. However, the above-mentioned first angle range, second angle range, and third angle range are only illustrative. According to other embodiments of the present invention, the angle ranges may vary based on the configuration and materials of the light emitting unit 200 and the protective layer 400.

In addition, according to some embodiments, the light emitting unit 200 of the display panel 10 may emit display light L0 at a forward viewing angle with the incident angle θ1 of zero in the first direction D1. As described above, according to some preferred embodiments, the angle-selective optical film 300 may be provided to substantially mostly transmit the display light L0. For example, with respect to other incident angles θ1, the angle-selective optical film 300 may exhibit maximum transmittance and minimum reflectance for the display light L0 at the forward viewing angle.

As described above, according to the architecture of each embodiment of the present invention, the display light within an expected angle range can be emitted to the protective layer 400 as much as possible, and the display light within an unexpected angle range can be reduced or avoided from being emitted to the protective layer 400. Alternatively, the intensity of display light L4 which is incident at an incident angle less than the preset angle, is transmitted to the protective layer 400 through the angle-selective optical film 300 and has the emergent angle θ4 smaller than the critical angle of total reflection γ can be greater than the intensity of the display light L4 which is directly transmitted to the protective layer 400 without the angle-selective optical film 300 and has the emergent angle θ4 smaller than the critical angle of total reflection γ. Alternatively, the reflectance of the angle-selective optical film 300 reflecting display light can vary by 50% or more under the angle variation not exceeding 10° within the preset range of the incident angle, so that the angle-selective optical film 300 has high transmittance for the display light when the incident angle is smaller than the preset angle, and the angle-selective optical film 300 has high reflectance for the display light when the incident angle is greater than the preset angle. As described above, according to some embodiments, by arranging the angle-selective optical film 300, the reflectance and/or the transmittance can have obvious sudden variation at the specific incident angle or a small range thereof, or the high transmittance and the high reflectance can have an obvious junction at a specific incident angle or a small range thereof. However, all of the above are illustrative only, and the present invention is not limited to this. Under the tendency that the angle-selective optical film 300 may have relatively high reflectance/low transmittance within a large incident angle range, and may have relatively low reflectance/high transmittance within a small incident angle range, there may be variation or adjustment on some details according to different embodiments.

As described above, according to some embodiments, the maximum emergent angle of the display light transmitted to the protective layer 400 through the angle-selective optical film 300 and having 10% or more of the maximum radiant intensity (for example, the radiant intensity at the forward viewing angle) can be smaller than the maximum emergent angle of the display light directly transmitted to the protective layer 400 without the angle-selective optical film 300 and having 10% or more of the maximum radiant intensity (for example, the radiant intensity at the forward viewing angle).

Next, the specific aspect of the optical structure Q according to an embodiment of the present invention will be further described below with reference to FIG. 3.

As described above, according to a display panel 20 in yet another embodiment, the optical structure Q for retrieving and reflecting various display light such as the display light L2′ reflected by the angle-selective optical film 300 may be a microstructure U formed on the bottom 202, the side wall 205, or the combination thereof. Specifically, the reflectance under a specular component exclude (SCE) mode of the microstructure U may be greater than 0, so that at least part of the display light L2′ or other display light may be subjected to non-specular reflection on the bottom 202, the side wall 205, or the combination thereof provided with the microstructure U. Therefore, when at least part of the display light L2′ or other display light is incident on the microstructure U at an incident angle α1 by taking the normal line N vertical to the substrate 100 as a reference, the microstructure U may change the light path of the display light L2′ or other display light to reflect at least part of the display light L2′ or other display light as the display light L3 at an emergent angle α2 different from the incident angle α1. As described above, by subjecting at least part of the display light L2′ or other display light to asymmetric non-specular reflection, the light selected and reflected by the angle-selective optical film 300 may be at least partially emitted out again at a reflection light path and angle which are not overlapped with the incident light path, and thus corresponding adjustment may be made to enable the display light L3 to be emitted at an angle which is easier for display light to pass through the angle-selective optical film 300 and the protective layer 400.

According to some embodiments, as shown in FIG. 3, the microstructure U may include a plurality of bumps M protruding towards the interior of the light emitting unit 200, and therefore at least part of display light L2′ or other display light may be scattered. In addition, according to some embodiments, the plurality of bumps M may be mainly formed at the bottom 202 of the light emitting unit 200, and may correspondingly receive and scatter the display light L2′ reflected by the angle-selective optical film 300 arranged at the top 201. However, the above is only illustrative, and other embodiments according to the present invention are not limited to this. For example, according to other embodiments, the plurality of bumps M may also be formed on the side wall 205 of the light emitting unit 200, and may reflect the display light which is not emitted towards the angle-selective optical film 300 by the light emitting unit 200 or the display light which is reflected by the bottom 202 but not emitted towards the angle-selective optical film 300. As described above, according to these embodiments, the display light G1 emitted to the side wall 205 may be further enabled to be reflected into the display light G2, which is then emitted to the angle-selective optical film 300.

In addition, according to this embodiment, the optical structure Q may also be an inclined surface V formed on the side wall 205. Based on the inclined surface V, the width W1 of the section of the light emitting unit 200 close to the top 201 in the direction parallel to the substrate 100 (for example, the second direction D2) may be greater than the width W2 of the section close to the bottom 202. Therefore, the display light G1 emitted to the side wall 205 may be more easily reflected into the display light G2, which is then emitted towards the angle-selective optical film 300.

As described above, according to some embodiments, an inner included angle K between the inclined surface V and the top 201 may be between 30° and 85°. However, according to other embodiments of the present invention, the inner included angle K in other embodiments of the present invention may also have other variations under the condition that at least part of the display light G1 may be reflected towards the angle-selective optical film 300.

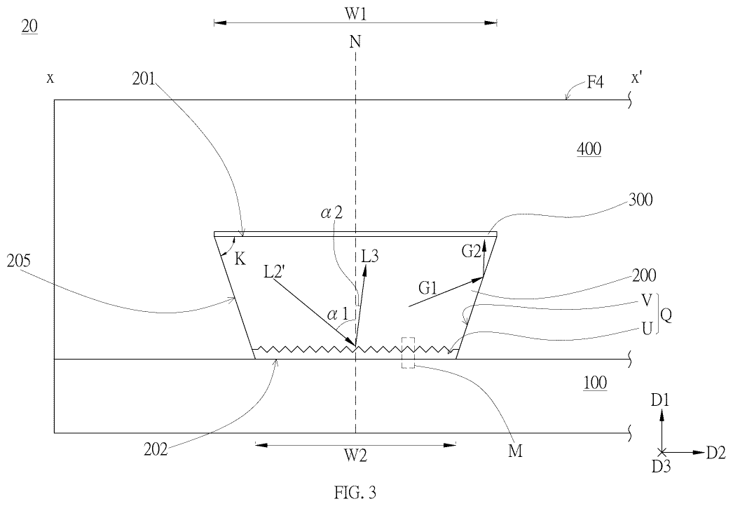

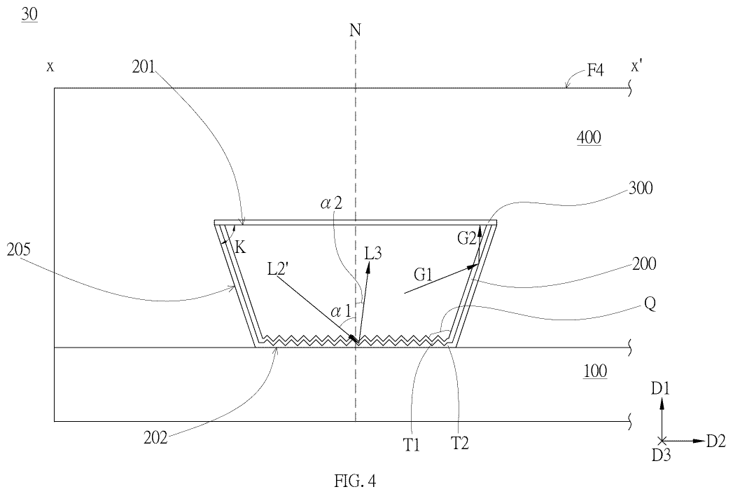

Then, with further reference to the display panel 30 in FIG. 4, in addition to the inclined surface V or the microstructure U as described above, according to some embodiments of the present invention, the optical structure Q may be covered with an insulating layer T1 and a reflecting layer T2, and the insulating layer T1 is relatively toward the inside of the light emitting unit 200. As described above, according to this aspect, by arranging the reflecting layer T2, the display light L2′ emitted to the bottom 202 and the display light G1 emitted to the side wall 205 may both be reflected in a larger proportion, and therefore the efficiency of retrieving the display light according to this embodiment can be improved. In addition, since the insulating layer T1 may be additionally provided on the reflecting layer T2, the unexpected electrical connection or short circuit between the reflecting layer T2 and the inside of the light emitting unit 200 can be reduced or avoided. However, the above is only illustrative. According to other embodiments of the present invention, the insulating layer T1 may not be arranged in case of no unexpected electrical connection or short circuit, or another insulating layer may be additionally arranged on the side of the reflecting layer T2 close to the substrate 100 to reduce or avoid the unexpected electrical connection or short circuit. As described above, there may be various variations according to other embodiments of the present invention.

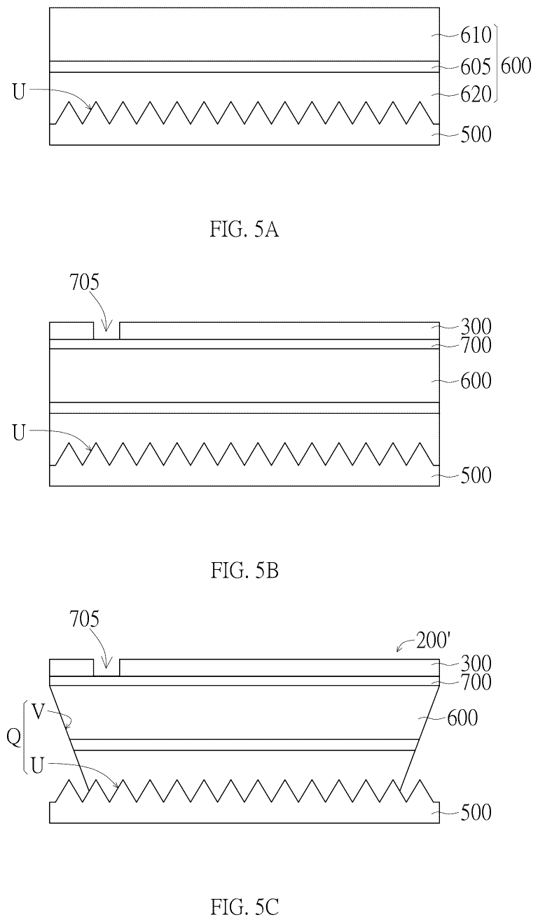

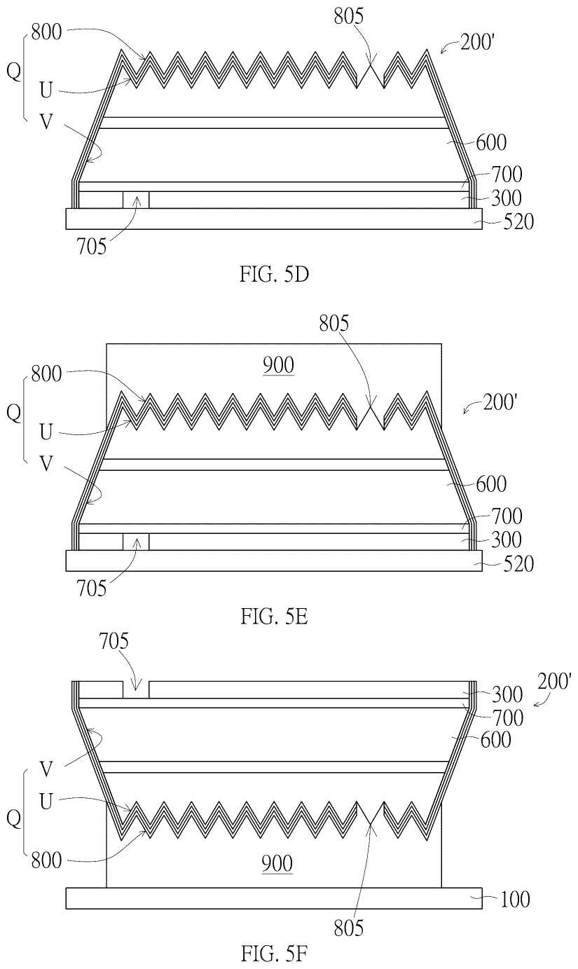

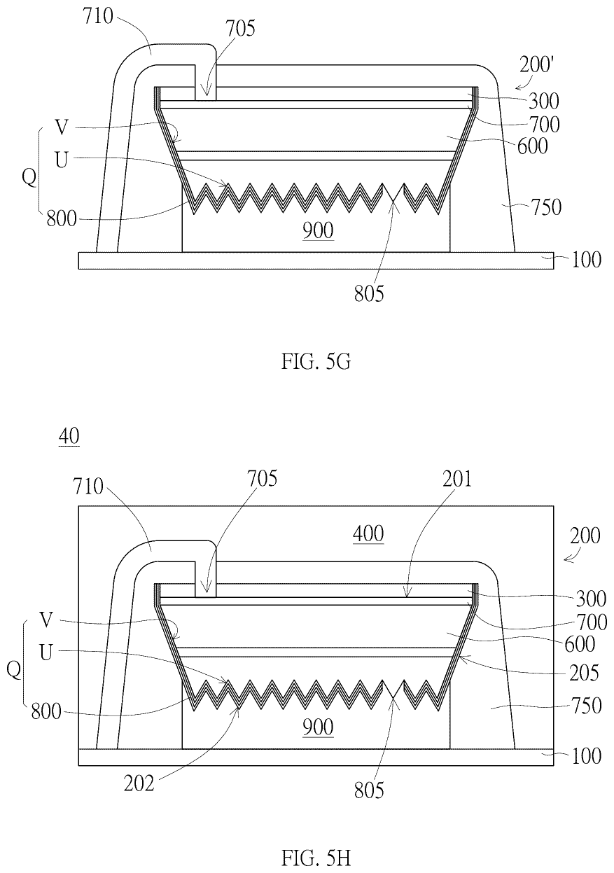

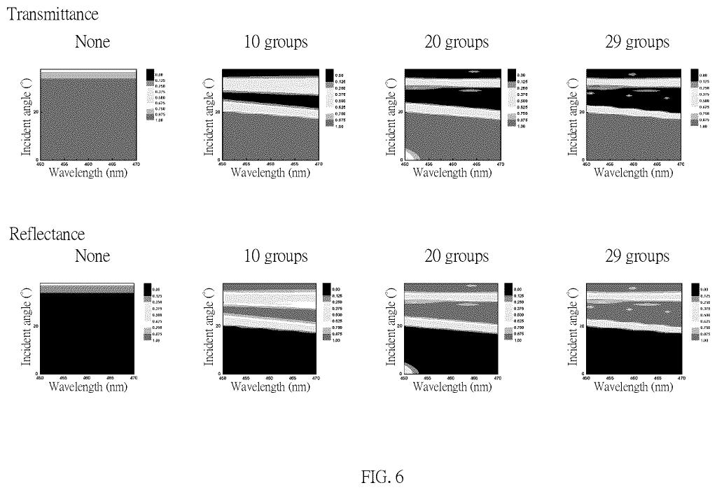

Next, with reference to FIG. 5A to FIG. 5H, the process of preparation of the light emitting unit of the display panel according to an embodiment of the present invention will be detailed below.

As described above, with reference to FIG. 5A, according to an embodiment of the present invention, a micro LED body 600 may be manufactured by depositing epitaxy based on a patterned sapphire substrate (PSS) 500. The micro LED body 600 may include a quantum well 605, a p-type gallium nitride layer 610 and an n-type gallium nitride layer 620 which are respectively arranged above and below the quantum well 605, and the like. As described above, the texture of the microstructure U may be naturally formed on the micro LED body 600 based on the texture of the PSS 500.

Then, with reference to FIG. 5B, according to this embodiment, an ITO electrode layer 700 and the angle-selective optical film 300 on the ITO electrode layer 700 may be further stacked on the micro LED body 600. An opening 705 preset to be connected to the ITO electrode layer 700 may be reserved on the angle-selective optical film 300.

Subsequently, with reference to FIG. 5C, according to this embodiment, the micro LED body 600 may be etched and/or cut to form individual and separate light emitting units 200′. Moreover, the inclined surface V which is a part of the optical structure Q may also be relatively etched and/or cut.

As described above, and with continuous reference to FIG. 5D, the light emitting unit 200′ may be inverted and transferred onto a transfer substrate 520. In addition, in order to improve the reflectance and insulation of the optical structure Q, a laminated structure 800 of the insulating layer (such as formed by SiO₂), the reflecting layer (such as formed by Ag), and the insulating layer (such as formed by SiO₂) may be sequentially deposited on the inverted light emitting unit 200′ according to this embodiment. As described above, the reflecting layer of the laminated structure 800 can improve the reflection retrieval ratio of the display light when being incident on the optical structure Q, and the insulating layer can reduce or avoid unexpected electrical connection or short circuit between the electrical material of the light emitting unit 200′ and other electronic components. As described above, according to some embodiments, an opening 805 may be reserved between the laminated structures 800 for connecting the electrical material of the light emitting unit 200′ to a desired electrode or component.

As described above, with further reference to FIG. 5E, after the laminated structures 800 are stacked and the opening 805 is reserved, a metal electrode 900 may be further stacked to connect the micro LED body 600 through the opening 805. Then, with reference to FIG. 5F, the light emitting unit 200′ on the transfer substrate 520 is inverted again and transferred onto the substrate 100, and thus at least one light emitting unit 200′ is arranged on the final finished substrate 100.

As described above, according to the manufacturing process of this embodiment, with reference to FIG. 5G, after the light emitting unit 200′ is arranged on the substrate 100, a wiring 710 for electrically connecting the ITO electrode layer 700 to other electrical components or circuit connection through the opening 705 may be further arranged, and the metal electrode 900 may be connected to the electrical component or circuit on the substrate 100, so that the arrangement of respective light emitting units 200′ is finished. In order to avoid unexpected electrical contact between the metal electrode 900 and the wiring 710, an insulating material layer 750 may be further arranged between the metal electrode 900 and the wiring 710 according to this embodiment.

Finally, with reference to FIG. 5H, according to this embodiment, the protective layer 400 made of optical adhesive may be stacked and covered on a semi-finished product of at least one constructed light emitting unit 200′, so that the finished light emitting units 200 and the corresponding display panel 40 are obtained. For example, the protective layer 400 may cover all the arranged light emitting units 200 in a spanning manner. As described above, in the display panel 40 obtained in this way, the angle-selective optical film 300 may be arranged on respective light emitting units 200, and the optical structure Q for correspondingly retrieving the display light is formed on the bottom 202, the side wall 205, or the combination thereof of the light emitting unit 200. Therefore, the display panel 40 of the micro LED with preset angle selectivity for the display light can be obtained. As described above, according to this embodiment, the display panel 40 may reduce or avoid the display light which is possibly and unexpectedly emitted to the protective layer 400 and is lost or trapped, so that the light emitting efficiency and the light emitting amount of the whole display light can be further improved.

According to some embodiments, a blue light micro LED is taken as an example. The optional angle-selective optical film 300 may be a film layer formed by sequentially stacking a plurality of groups of TiO₂/SiO₂, in which the refractive index of the material (such as GaN) of the light emitting unit 200 itself may be 2.4, and the refractive index of the material (such as optical adhesive) of the protective layer 400 may be 1.5. As described above, this architecture is taken as an example. FIG. 6 shows a specific selective property of the angle-selective optical film 300 formed by stacking different groups. The upper row presents the transmittance, and the lower row presents the reflectance; and the sequence from left to right is that no angle-selective optical film is arranged, the angle-selective optical film composed of 10 groups of TiO₂/SiO₂ is arranged, the angle-selective optical film composed of 20 groups of TiO₂/SiO₂ is arranged, and the angle-selective optical film composed of 29 groups of TiO₂/SiO₂ is arranged. As described above, it can be definitely seen that, for the display light with the same wavelength, the reflectance of the angle-selective optical film reflecting the display light can vary based on the difference of incident angles. For example, for the display light with the same wavelength (such as one wavelength within the visible light range), the reflectance of the angle-selective optical film reflecting the display light can increase approximately along with the increase of the incident angle. As described above, as shown in FIG. 6, by arranging the angle-selective optical film, the reflectance and the transmittance (the reflectance and the transmittance during emitting from the light emitting unit 200 to the angle-selective optical film 300) of the display light which are originally within an incident angle range of about 20° and 40° can obviously vary, and the variation rate may increase along with the increase of the groups of the stacked layers contained in the angle-selective optical film within a certain range. Therefore, boundaries separating the blocks respectively having high reflectance and high transmittance can be changed within a range of 15° to 45° of a preset angle of the incident angles, so as to reflect and retrieve the display light within a range of 20° to 40° which may not be emitted from the protective layer 400 to the outside.

According to some embodiments, the preset thickness of the angle-selective optical film 300 may be smaller than 2 μm. More stacked layer groups formed by stacking a plurality of different material layers may be configured as much as possible under the preset thickness. However, the above is only illustrative. Other embodiments according to the present invention are not limited to this.

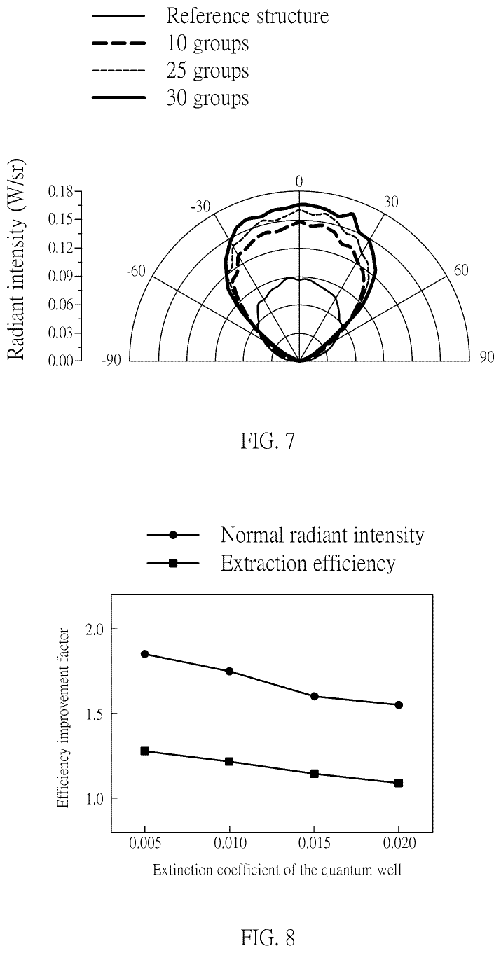

As described above, when the light emitting unit, the angle-selective optical film, and the optical structure of the display panel are arranged similar to the example aspect of the architecture in FIG. 5H and the angle-selective optical film in FIG. 6, with reference to FIG. 7, according to an embodiment, the radiant intensity of the display panel can be remarkably improved finally. In detail, as shown in FIG. 7, a blue light micro LED is taken as an example. A “reference structure” is the optical structure with the light emitting unit provided with a reflecting layer made of Ag, but no angle-selective optical film is arranged. “10 groups”, “25 groups” and “30 groups” refer to further arranging the angle-selective optical films composed of 10 groups, 25 groups, and 30 groups of TiO₂/SiO₂ on the “reference structure”. As described above, it can be seen that, by arranging and matching the angle-selective optical film and the optical structure capable of reflecting, the light emitting amount of the light emitted within the inclination angle range of about +/−45° can be remarkably increased, it is proved that the angle-selective optical film can screen different incident angles, the actual proportion of the light emitted from the light emitting unit can be increased, thereby enhancing the overall radiant intensity of the display panel.

According to this embodiment, the external quantum efficiency (EQE) of the display panel to the outside is respectively 26.7%, 33.5%, 34.8%, and 35.7%, corresponding to the “reference structure”, “10 groups”, “25 groups”, and “30 groups”. As shown above, according to the architecture of this embodiment, the light emitting efficiency of the entire display panel to substantially emit light to the outside can be further improved.

As described above, FIG. 8 further shows light emission test results of a simulation structure of normal radiant intensity at the front viewing angle of the normal line vertical to the substrate and extraction efficiency of integrated emission at all angles under different extinction coefficients relative to quantum wells of the light emitting units prepared from micro LEDs and under the architectures of the angle-selective optical film and the optical structure of capable of reflecting provided according to each embodiment of the present invention. The efficiency improvement factor of the “30 groups” relative to the “reference structure” in FIG. 7 is taken as an example. As shown in FIG. 8, it can be seen that, according to the architecture in each embodiment of the present invention, if the extinction coefficient of the quantum well is 0.005, the normal radiant intensity can be increased to nearly two times, and the overall extraction efficiency is increased to nearly 1.3 times, although the degree of the improvement is relatively low. Therefore, according to each embodiment of the present invention, the normal radiant intensity and the extraction efficiency of accumulated emission at all angles can be significantly improved. In particular, according to each embodiment of the present invention, the display light that is possibly lost and trapped can be retrieved and can be emitted in an expected angle range, thereby significantly improving the normal radiant intensity of the display panel.

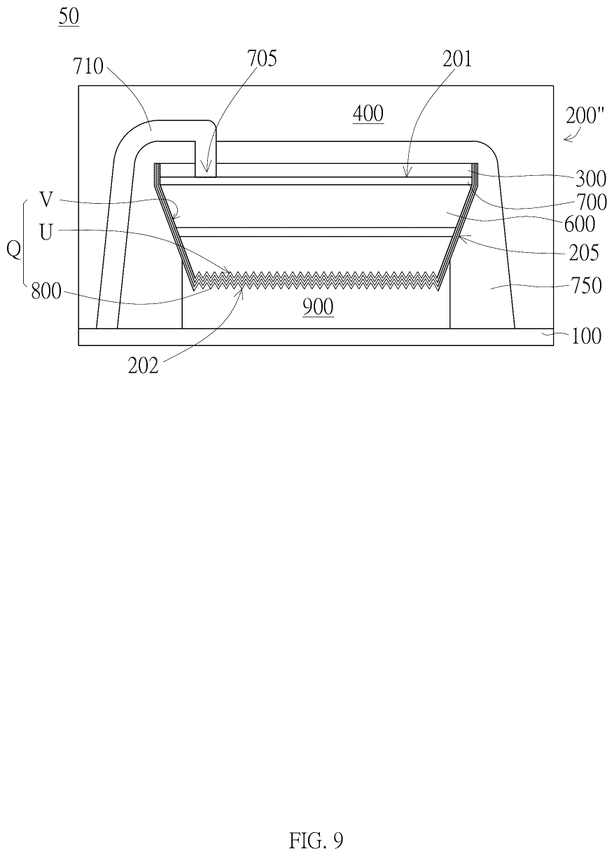

In addition, it is specifically described in the process shown in FIG. 5A to FIG. 5H that the tested light emitting unit 200 of the above aspect, such as the blue light micro LED or a green light micro LED, is formed by the texture of a patterned sapphire substrate 500. However, with reference to FIG. 9, the process that can be employed in other embodiments of the present invention is not limited to this under the condition that the optical structure Q such as the microstructure U can be provided. For example, when the display panel 50 shown in FIG. 9 includes a light emitting unit 200″ of a red light micro LED, the microstructure U may also be formed by, for example, etching the bottom of the light emitting unit 200″ based on the technical means other than the texture of the patterned sapphire substrate 500. The material commonly used for the red light micro LED such as GaP and/or AlInP can be used for making the main body of the light emitting unit 200″, but it is not limited to this. As described above, according to some embodiments, in a case that the angle-selective optical film 300 and the optical structure Q are provided and the extinction coefficient of the quantum well of the red light micro LED is 0.16, at least 10% or more of the brightness increase can be achieved based on this architecture.

Besides different manufacturing processes, the light emitting unit 200″ according to this embodiment may have the same or similar aspect or known structure composition as described in each above embodiment, which will not be listed here in detail. In addition, although the aspect that opposite electrodes of the light emitting unit are arranged on the top and the bottom of the light emitting unit respectively is specifically shown here, according to other embodiments, it is possible for the two electrodes to be arranged either both on the top or both on the bottom of the light emitting unit. As described above, those skilled in the art should correspondingly deduce the aspects and variations from examples shown in the description and the accompanying drawings, which will not be redundantly listed here.

In conclusion, the display panel including the light emitting unit can be provided according to each embodiment of the present invention, and the light emitting amount and the light emitting efficiency of the display light emitted by the light emitting unit actually to the outside can be further improved based on the angle-selective optical film and the optical structure capable of reflecting. Therefore, according to each embodiment of the present invention, invalid light emission can be reduced or avoided, and display light of the whole display panel can be improved or promoted.

The foregoing is only some of the preferred embodiments of the present invention. It is to be noted that, without departing from the spirit and principles of the present invention, the present invention may be subject to various changes and modifications Those skilled in the art should be aware that the present invention is defined by the appended claims, and under the intent of the present invention, all possible changes, such as replacement, combination, modification and conversion, do not exceed the scope defined by the scope of the appended claims of the present invention.

What is claimed is:

1. A display panel, comprising:
a substrate;
a light emitting unit disposed on the substrate and having a top facing away from the substrate, a bottom opposite to the top, and a side wall connecting the top and the bottom;
an angle-selective optical film disposed on the top of the light emitting unit; and
a protective layer covering the light emitting unit and the angle-selective optical film, wherein,
with respect to a normal line vertical to the substrate, display light emitted to the angle-selective optical film by the light emitting unit has an incident angle, and a ratio of the display light reflected by the angle-selective optical film varies at least partially based on the change of the incident angle; and
wherein the bottom, the side wall, or a combination thereof has an optical structure configured to at least partially reflect the display light reflected from the angle-selective optical film.

2. The display panel according to claim 1, wherein the optical structure is a microstructure formed on the bottom, the side wall, or the combination thereof, and reflectance of the microstructure under a specular component exclude (SCE) mode is greater than 0, so that at least part of the display light is subjected to non-specular reflection at the bottom, the side wall, or the combination thereof provided with the microstructure.

3. The display panel according to claim 2, wherein the microstructure comprises a plurality of bumps protruding towards the inside of the light emitting unit.

4. The display panel according to claim 3, wherein the plurality of bumps are formed on the bottom of the light emitting unit.

5. The display panel according to claim 1, wherein the optical structure is an inclined surface formed on the side wall; and based on the inclined surface, a width of a section of the light emitting unit close to the top along a direction parallel to the substrate is greater than a width of a section close to the bottom.

6. The display panel according to claim 5, wherein an inner included angle between the inclined surface and the top is 30° to 85°.

7. The display panel according to claim 1, wherein reflectance of the angle-selective optical film reflecting the display light is greater than transmittance of the angle-selective optical film transmitting the display light when the incident angle is greater than a preset angle.

8. The display panel according to claim 1, wherein a variation rate of the reflectance of the angle-selective optical film reflecting the display light when the incident angle is greater than a preset angle is greater than a variation rate of the reflectance of the angle-selective optical film reflecting the display light when the incident angle is smaller than the preset angle.

9. The display panel according to claim 8, wherein the reflectance of the angle-selective optical film reflecting the display light has a variation of 50% or more under an angle variation not exceeding 10° within a preset range of the incident angle, so that the angle-selective optical film has high transmittance for the display light when the incident angle is smaller than the preset angle, and the angle-selective optical film has high reflectance for the display light when the incident angle is greater than the preset angle.

10. The display panel according to claim 7, wherein the preset angle is an angle between 15° and 45°.

11. The display panel according to claim 8, wherein the preset angle is an angle between 15° and 45°.

12. The display panel according to claim 10, wherein the preset angle is an angle between 20° and 30°.

13. The display panel according to claim 11, wherein the preset angle is an angle between 20° and 30°.

14. The display panel according to claim 12, wherein the preset angle is an angle between 20° and 24°.

15. The display panel according to claim 13, wherein the preset angle is an angle between 20° and 24°.

16. The display panel according to claim 1, wherein the display light has a critical angle of total reflection at an interface between the protective layer and the outside of the protective layer, and an emergent angle of the display light transmitted to the protective layer through the angle-selective optical film is smaller than the critical angle of total reflection.

17. The display panel according to claim 1, wherein the display light has a critical angle of total reflection at an interface between the protective layer and the outside of the protective layer, and an emergent angle of the display light which is incident to the angle-selective optical film at a preset angle and correspondingly passes through the angle-selective optical film is equal to or smaller than the critical angle of total reflection; and
the reflectance of the angle-selective optical film reflecting the display light is greater than the transmittance of the angle-selective optical film transmitting the display light when the incident angle is greater than the preset angle.

18. The display panel according to claim 1, wherein the display light has a critical angle of total reflection at an interface between the protective layer and the outside of the protective layer, and the intensity of the display light which is transmitted to the protective layer through the angle-selective optical film and has an emergent angle smaller than the critical angle of total reflection is greater than the intensity of the display light which is directly transmitted to the protective layer without the angle-selective optical film and has the emergent angle smaller than the critical angle of total reflection.

19. The display panel according to claim 1, wherein the maximum emergent angle of the display light which is transmitted to the protective layer through the angle-selective optical film and has 10% or more of the maximum radiant intensity is smaller than the maximum emergent angle of the display light which is directly transmitted to the protective layer without the angle-selective optical film and has 10% or more of the maximum radiant intensity.

20. The display panel according to claim 1, wherein the optical structure is covered with an insulating layer and a reflecting layer, and the insulating layer relatively toward the inside of the light emitting unit.
